(19) United States
(12) Patent Application Publication
(10) Pub. No.: US 2023/0079287 A1
(43) Pub. Date: Mar. 16, 2023

(54) ELECTRONIC APPARATUS

(71) Applicant: Lenovo (Singapore) Pte. Ltd., Singapore (SG)

(72) Inventors: Masahiro Kitamura, Kanagawa (JP); Yusuke Onoue, Kanagawa (JP); Takuroh Kamimura, Kanagawa (JP)

(73) Assignee: Lenovo (Singapore) Pte. Ltd., Singapore (SG)

(21) Appl. No.: 17/859,714

(22) Filed: Jul. 7, 2022

(30) Foreign Application Priority Data
Sep. 16, 2021 (JP) 2021-151151

(51) Int. Cl. G06F 1/20; H05K 7/20; G06F 1/16

(52) U.S. Cl. CPC G06F 1/203; H05K 7/2039; G06F 1/206; G06F 1/1669

(57) ABSTRACT

An electronic apparatus uses the cooling effect of a vapor chamber and includes: a chassis; a motherboard which is provided in the chassis and has a CPU mounted on a front surface thereof; a vapor chamber having a working fluid sealed in a hermetically sealed space formed between two metal plates; a stud fixed to the upper surface of the vapor chamber; and a screw fixing the stud and the motherboard. The CPU is thermally connected to the upper surface of the vapor chamber. The motherboard has a mounting hole formed therein, and the screw is screwed to the stud through the mounting hole from the rear surface of the motherboard. The CPU is rectangular, and four studs and four screws are provided at positions in the vicinity of the four corners of the CPU.

### CROSS-REFERENCE TO RELATED APPLICATIONS

This application claims priority to Japanese Patent Application No. 2021-151151 filed on Sep. 16, 2021, the contents of which are hereby incorporated herein by reference in their entirety.

### BACKGROUND

### Technical Field

The present invention relates to an electronic apparatus provided with a vapor chamber.

### Description of Related Art

An electronic apparatus such as a laptop PC has a heat generating element such as a CPU. Such an electronic apparatus has a cooling module mounted in a chassis to absorb the heat generated by the heat generating element and dissipate the heat to the outside. Japanese Unexamined Patent Application Publication No. 2019-32134 discloses a configuration in which a plate-shaped vapor chamber is connected to a CPU. The vapor chamber has a working fluid sealed in a hermetically sealed space formed between two metal plates, exhibiting excellent cooling efficiency.

FIG. 7 is a schematic sectional view of a chassis in a laptop PC 500 according to a comparative example. In the chassis of the laptop PC 500, a motherboard 508 and a vapor chamber 510 are placed in such a manner as to be stacked between an upper cover 504, which is provided with a keyboard 502, and a lower cover 506. The vapor chamber 510 is in thermal contact with a CPU 512 mounted on the motherboard 508.

A plurality of mounting holes 514 are formed in the vapor chamber 510. Further, the vapor chamber 510 is fixed by screwing screws 516 through the mounting holes 514 to studs 518 provided on the motherboard 508. The plurality of mounting holes 514 are provided in the vicinity of the CPU 512 (e.g., in the vicinity of the four corners), and the vapor chamber 510 and the CPU 512 can be brought into contact with a moderately strong pressure, thus making it possible to improve heat transfer performance.

However, providing the vapor chamber 510 with the mounting holes 514 reduces the volume of the hermetically sealed space accordingly and also interferes with the flow of a working fluid, resulting in deterioration of cooling effect. In addition, a predetermined area is required around the mounting holes 514 mainly to secure a clearance from the heads of the screws 516 and to secure partition walls 510a, leading to a concern that the cooling effect is further deteriorated. Providing the mounting holes 514 in the vicinity of the CPU 512 affects heat reception and heat dissipation from the CPU 512, resulting in further deteriorated cooling effect. It is conceivable to provide a mounting piece for mounting the screws 516 in such a manner as to project from the periphery of the vapor chamber 510, but this would increase a layout space, and separate the screws 516 from the CPU 512, thus causing the contact pressure between the vapor chamber 510 and the CPU 512 to decrease.

### SUMMARY

The present invention has been made in view of the problems described above, and an object of the invention is to provide an electronic apparatus capable of effectively using the cooling effect of a vapor chamber.

In order to solve the problems and fulfill the object described above, an electronic apparatus in accordance with an aspect of the present invention is an electronic apparatus including: a chassis; a substrate which is provided in the chassis and has a heat generating element mounted on a front surface thereof; a plate-shaped vapor chamber having a working fluid sealed in a hermetically sealed space formed between two metal plates; a stud fixed to one surface of the vapor chamber; and a screw fixing the stud and the substrate, wherein the heat generating element is thermally connected to the one surface of the vapor chamber, a mounting hole is formed in the substrate, and the screw is screwed to the stud through the mounting hole from a rear surface of the substrate.

In such an aspect, the stud is provided on one surface of the vapor chamber, and the screw is screwed in from the one surface. Therefore, the screw does not come in contact with or penetrate the vapor chamber, so that it is not necessary to provide a through hole or a recessed portion for the screw. Consequently, the vapor chamber has no performance loss, thus enabling the effective use of cooling effect.

The heat generating element may be rectangular, and four each of the studs, the screws, and the mounting holes may be provided at positions in the vicinity of the four corners of the heat generating element. This enables the vapor chamber and the heat generating element to be brought into contact with each other with a moderately strong pressure, thus making it possible to improve heat transfer performance.

Two frame bars may be provided on the one surface of the vapor chamber, and each of the frame bars may include a parallel portion which extends along two parallel edges of the heat generating element and a proximate portion which extends further from the parallel portion in both directions and expands in a direction in which the distance between the two frame bars narrows, and the studs may be provided on the proximate portions. Providing the studs on the proximate portions makes it easy to place the studs in the vicinity of the four corners of the heat generating element.

A reinforcing frame shaped along the outline of the heat generating element may be provided on the rear surface of the substrate, and the reinforcing frame may have through holes which are in communication with the mounting holes and through which the screws pass. Providing the reinforcing frame prevents the substrate from being deformed even if the screws are firmly screwed.

A detachable keyboard may be provided on the upper surface of the chassis, the substrate may be provided such that the rear surface thereof is on the upper side, and the head of the screw may be exposed at the top of the chassis in a state in which the keyboard has been removed.

According to the above-described aspects of the present invention, the studs are provided on one surface of the vapor chamber, and the screws are screwed in from the one surface. Therefore, the screws do not come in contact with or penetrate the vapor chamber, so that it is not necessary to provide through holes or recessed portions for the screws. Consequently, the vapor chamber has no performance loss, thus enabling the effective use of cooling effect.

### BRIEF DESCRIPTION OF THE DRAWINGS

FIG. 1 is a schematic plan view illustrating an electronic apparatus according to an embodiment observed from above;

FIG. 2 is a plan view schematically illustrating the internal structure of a chassis;

FIG. 3 is a schematic bottom view of a cooling module;

FIG. 4 is a perspective view of a vapor chamber provided with frames;

FIG. 5 is a schematic sectional view of the chassis;

FIG. 6 is a sectional perspective view of the vapor chamber and a CPU, and a part of a peripheral area thereof; and

FIG. 7 is a schematic sectional view of a chassis of a laptop PC according to a comparative example.

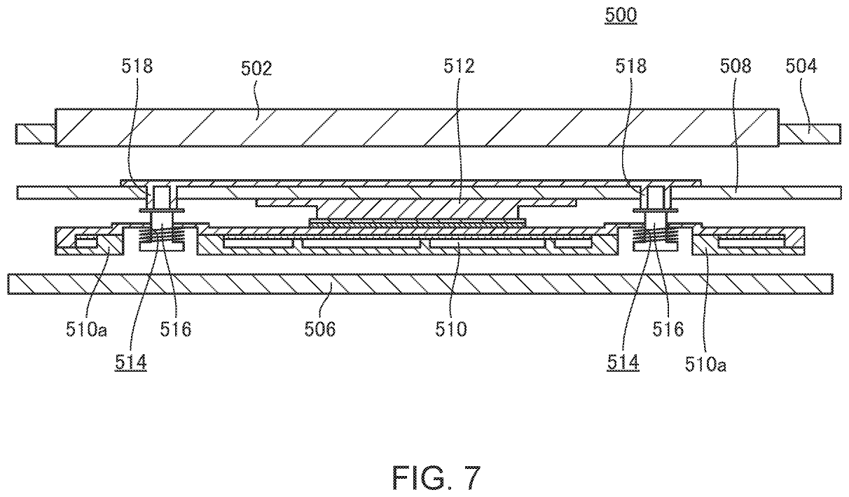

### DETAILED DESCRIPTION

The following will describe in detail an embodiment of an electronic apparatus according to the present invention with reference to the accompanying drawings. It should be noted that the present invention is not limited by the embodiment.

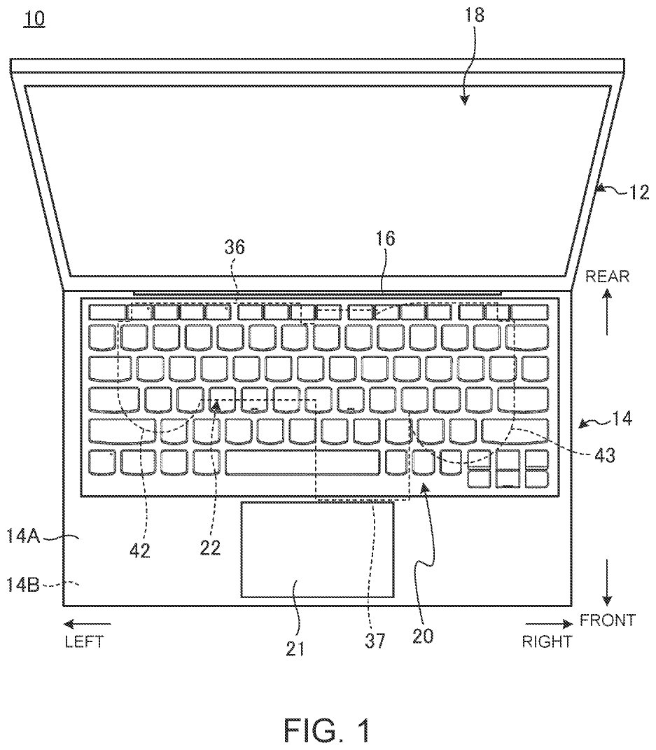

FIG. 1 is a schematic plan view illustrating an electronic apparatus 10 according to an embodiment observed from above. As illustrated in FIG. 1, the electronic apparatus 10 is a clamshell laptop PC that has a display chassis 12 and a chassis 14 relatively rotatably connected by a hinge 16, and is referred to as a so-called mobile workstation. An electronic apparatus according to the present invention may be, for example, a desktop PC, a tablet PC, a mobile phone, a smartphone, a game machine, or the like, other than the laptop PC.

The display chassis 12 is a thin, flat box. A display 18 is mounted on the display chassis 12. The display 18 is composed of, for example, an organic EL (OLED: Organic Light Emitting Diode) or a liquid crystal.

Hereinafter, the chassis 14 and the elements mounted on the chassis 14 will be described in a state in which the chassis 12 and 14 are opened as illustrated in FIG. 1. The posture for visually recognizing the display 18 will be the reference posture, and a front relative to the reference posture will be referred to as the front, a back relative thereto will be referred to as the rear, a width direction will be referred to as left and right, and a height direction (the thickness direction of the chassis 14) will be referred to as top and bottom.

The chassis 14 is a thin, flat box. The chassis 14 is composed of a cover member 14A that forms the upper surface and four peripheral side surfaces, and a cover member 14B that forms the lower surface. The upper cover member 14A has a substantially bathtub shape with an open bottom. The lower cover member 14B has a substantially flat plate shape, and serves as a lid that closes the bottom opening of the cover member 14A. The cover members 14A and 14B are overlapped in the thickness direction and are detachably connected to each other. A keyboard 20 and a touch pad 21 are provided on the upper surface of the chassis 14. The rear end portion of the chassis 14 is connected to the display chassis 12 by using a hinge 16.

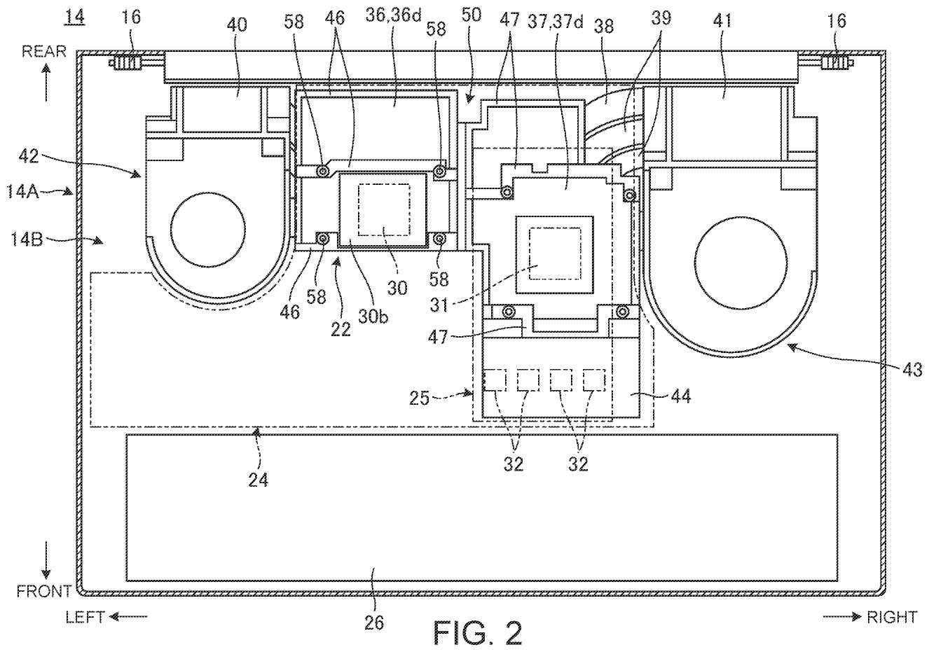

FIG. 2 is a plan view schematically illustrating the internal structure of the chassis 14, and a schematic plan sectional view illustrating the chassis 14 cut at a position slightly below the keyboard 20.

As illustrated in FIG. 2, a cooling module 22, a motherboard 24, a sub-board 25, and a battery unit 26 are provided inside the chassis 14. The chassis 14 further includes a variety of electronic components, mechanical components, and the like.

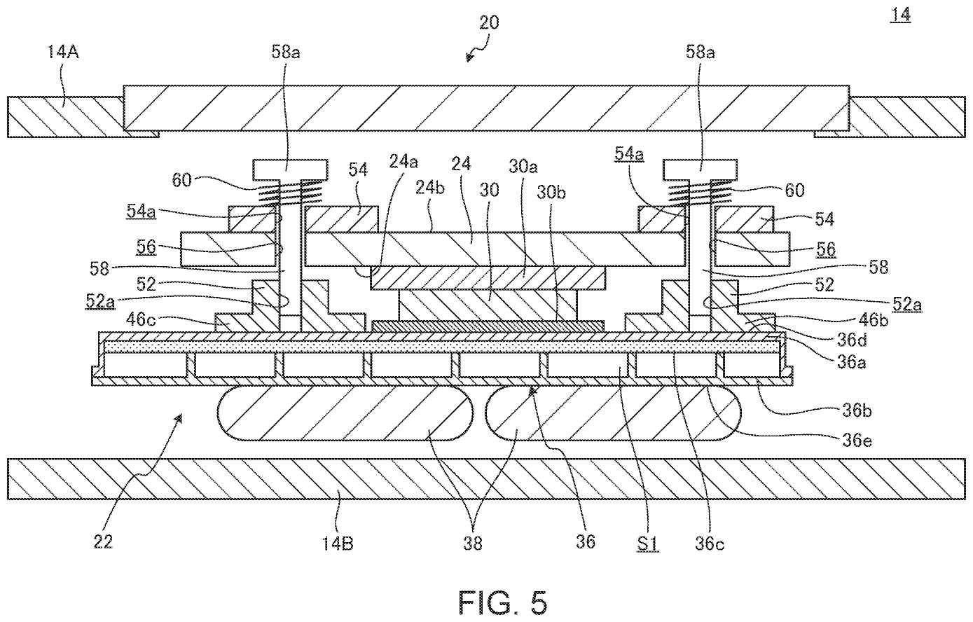

The motherboard 24 is the mainboard of the electronic apparatus 10. The motherboard 24 is placed adjacently to the rear of the chassis 14 and extends along a left-right direction. The motherboard 24 is a printed circuit board on which a variety of electronic components such as a communication module, memories, and connection terminals in addition to a CPU (Central Processing Unit) 30 are mounted. The motherboard 24 is placed under the keyboard 20 and screwed to the rear surface of the keyboard 20 or the inner surface of the cover member 14A. The upper surface of the motherboard 24 serves as a surface of installation to the cover member 14A, and the lower surface thereof serves as a mounting surface 24a for the CPU 30 and the like (refer to FIG. 5). The CPU 30 is placed substantially at the left-right center of the mounting surface 24a of the motherboard 24. The CPU 30 performs calculations for main control and processing of the electronic apparatus 10. A symbol 30a in FIG. 5 denotes a package substrate on which the CPU (die) 30 is mounted. A symbol 30b in FIG. 5 denotes a heat receiving plate. In the present application, regarding the front and rear of the motherboard 24, the mounting surface 24a is also referred to as a front surface 24a, and the surface opposite thereto is referred to as a rear surface 24b. The front surface 24a is the surface having the CPU 30 mounted thereon. In the motherboard 24, many electronic components are mounted on the front surface 24a, but electronic components other than the CPU 30 may be mounted on the rear surface 24b.

The sub-board 25 is an expansion card having a smaller outer shape than the motherboard 24. The sub-board 25 is a printed circuit board on which a variety of electronic components such as a GPU (Graphics Processing Unit) 31 and a power component 32 are mounted. The sub-board 25 is stacked in the vicinity of the right end of the mounting surface 24a of the motherboard 24 (refer to FIG. 2), and the GPU 31 is mounted substantially at the center thereof. The sub-board 25 is connected to a connector 33 mounted on the motherboard 24 (refer to FIG. 5) thereby to be electrically connected to the motherboard 24. The upper surface of the sub-board 25 is the surface to be mounted on the mounting surface 24a of the motherboard 24, and the lower surface thereof serves as a mounting surface 25a for the GPU 31 and the like. The GPU 31 performs calculations necessary for image depiction such as 3D graphics. A symbol 31a in FIG. 5 denotes a package substrate on which the GPU (die) 31 is mounted.

The battery unit 26 is a rechargeable battery that serves as a power source for the electronic apparatus 10. The battery unit 26 is placed in front of the motherboard 24 and extends to the left and right along the front end portion of the chassis 14.

The CPU 30 and the GPU 31 are heat generating elements having the largest amount of heat generated among the electronic components mounted in the chassis 14. Therefore, the cooling module 22 absorbs and diffuses the heat generated by the CPU 30 and the GPU 31, and further discharges the heat to the outside of the chassis 14. The cooling module 22 is stacked on the lower surfaces (below the mounting surfaces 24a and 25a) of the motherboard 24 and the sub-board 25.

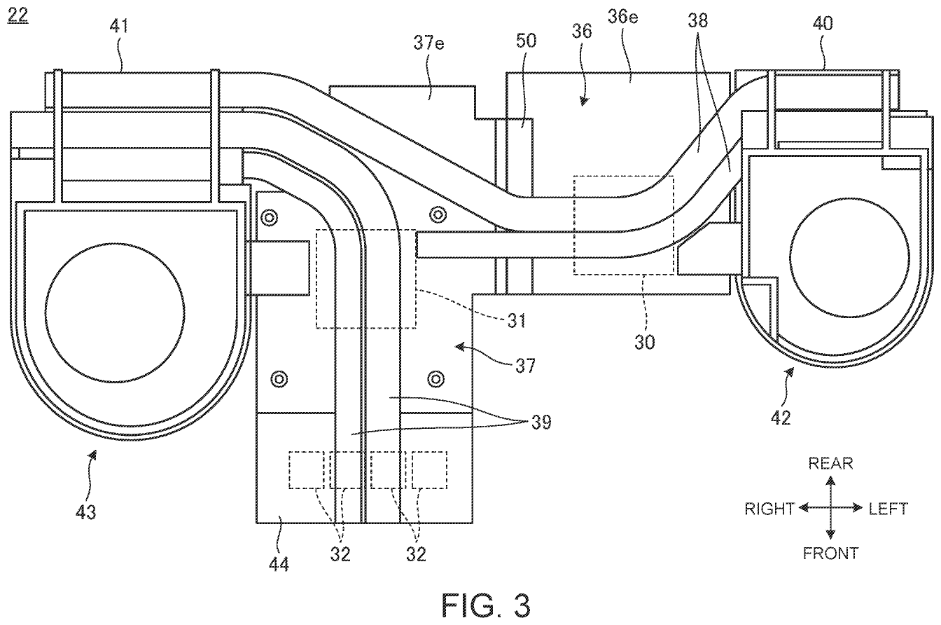

FIG. 3 is a schematic bottom view of the cooling module 22.

As illustrated in FIG. 2 and FIG. 3, the cooling module 22 includes vapor chambers 36 and 37 arranged on left and right, a heat pipe 38 composed of a set of two pipes, a heat pipe 39 composed of a set of two pipes, and a pair of left and right cooling fins 40 and 41, a pair of left and right blower fans 42 and 43, and a thermally conductive plate 44.

The vapor chambers 36 and 37 are plate-shaped heat transfer devices. The vapor chamber 36 has a hermetically sealed space S1 formed between two thin metal plates 36a and 36b (refer to FIG. 5), a working fluid being sealed in the hermetically sealed space S1. The metal plates 36a, 36b are formed of a metal having a high thermal conductivity such as aluminum, copper or stainless steel. The hermetically sealed space S1 provides a flow path through which a sealed working fluid flows while undergoing a phase change. Examples of the working fluid include water, chlorofluorocarbon substitute, acetone, and butane. In the hermetically sealed space S1, a wick 36c, which feeds a condensed working fluid by a capillary phenomenon, is provided (refer to FIG. 5). The wick 36c is formed of, for example, a porous material such as a mesh in which fine metal wires are woven into a flocculent shape or a microchannel. The vapor chamber 37 has the same basic configuration as that of the vapor chamber 36 described above, except that the outer shape is larger than that of the vapor chamber 36 and the plate thickness is slightly thinner.

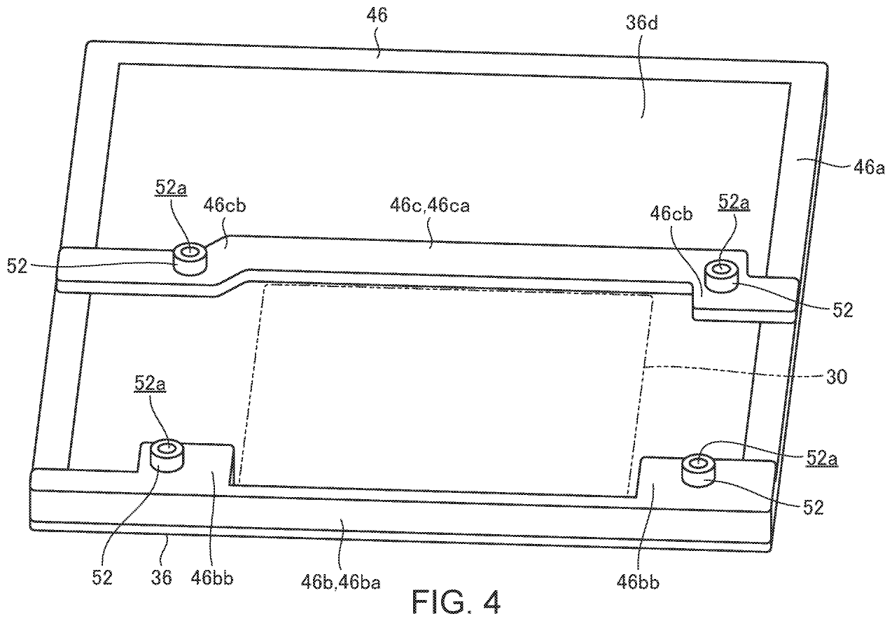

The vapor chambers 36 and 37 are thin and easily deformed. Therefore, the vapor chambers 36 and 37 are reinforced by joining (e.g., by soldering) frames 46 and 47 to the outer peripheral edges and the central portions of upper surfaces 36d and 37d, respectively (refer to FIG. 2 and FIG. 4). The frames 46 and 47 are made of a metal such as stainless steel, and are formed of rods that are thicker than the vapor chambers 36, 37 into frame shapes. The configuration of the frame 46 will be further described later.

The heat pipe 38 is a pipe-shaped heat transfer device. In the present embodiment, two heat pipes 38 and 38 are used in a set of two arranged at front and rear; however, one or three or more heat pipes may alternatively be used. The heat pipe 38 is formed by crushing a metal pipe thinly and flatly to have an elliptical cross section, and a working fluid is sealed in the hermetically sealed space formed in the metal pipe. The metal pipe is made of a metal having a high thermal conductivity such as aluminum, copper, or stainless steel. The hermetically sealed space provides a flow path through which a sealed working fluid flows while undergoing a phase change. Examples of the working fluid include water, chlorofluorocarbon substitute, acetone, and butane. In the hermetically sealed space, a wick, which feeds a condensed working fluid by a capillary phenomenon, is provided. The wick is formed of, for example, a porous material such as a mesh in which fine metal wires are woven into a flocculent shape or a microchannel. The heat pipe 39 has the same basic configuration as that of the heat pipe 38 described above, except that the length and the path are different.

The heat pipe 38 is curved in the center toward the front and extends in the left-right direction as a whole. The heat pipe 38 is joined to the lower surface 36e of the vapor chamber 36 at a position where a substantially central portion serving as a heat receiving portion overlaps with the CPU 30. The heat pipe 39 is arranged in a substantially L shape as a whole. The heat pipe 39 is joined to a lower surface 37e of the vapor chamber 37 at a position where a substantially central portion serving as a heat receiving portion overlaps with the GPU 31.

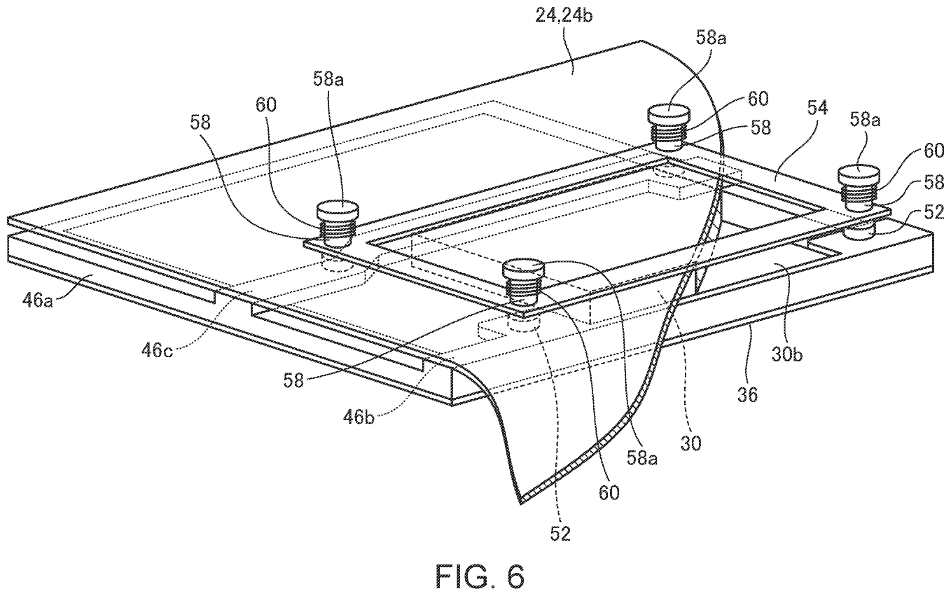

Thus, the heat generated by the CPU 30 and the GPU 31 is absorbed and diffused in the vapor chambers 36 and 37, and is efficiently transported to the cooling fins 40 and 41 via the heat pipes 38 and 39 and then discharged to the outside of the chassis 14 by the air blow of the blower fans 42 and 43. In the present embodiment, the vapor chamber 36 and the vapor chamber 37 are connected by a connection section 50, but may alternatively be independent of each other. In the following FIG. 4, FIG. 5, and FIG. 6, the connection section 50 is omitted.

The following will further describe the structure for fixing the vapor chamber 36 and the motherboard 24. First, the frame 46 provided on the vapor chamber 36 will be described.

FIG. 4 is a perspective view of the vapor chamber 36 provided with the frame 46. In FIG. 4, the rectangular area indicated by the virtual line is the area where CPU 30 is in contact. In other words, CPU 30 is rectangular. The vapor chamber 36 has an area sufficiently larger than the contact area of the CPU 30. As described above, the frame 46 is joined to the upper surface 36d of the vapor chamber 36 by solder or the like.

The frame 46 has a frame portion 46a extending along three continuous edges of the vapor chamber 36, and two frame bars 46b and 46c. The frame bar 46b connects the ends of the frame portion 46a together. The frame bar 46c extends across and connects the two opposing edges of the frame portion 46a. The frame bars 46b and 46c are formed to be thicker than the frame portion 46a to have higher strength.

The two frame bars 46b and 46c include parallel portions 46ba and 46ca, which extend along the two parallel edges of the CPU 30, and proximate portions 46bb and 46cb, which extend further in both directions from the parallel portions 46ba and 46ca and project in a direction in which the distance between the two frame bars narrows. The four proximate portions 46bb and 46cb are provided with studs 52. A screw hole 52a is formed in each of the studs 52. The screw hole 52a has a female thread formed therein, but tapping may alternatively be adopted by screwing screws 58, which will be described later.

The studs 52 are made of, for example, a SUS material, and are press-fitted into the proximate portions 46bb and 46cb. In other words, the studs 52 are fixed to the upper surface 36d of the vapor chamber 36 through the frame 46. As is obvious from FIG. 4, the four studs 52 are provided in the vicinity of the four corners of the rectangular portion with which the CPU 30 is in contact. The frame 46 has a function of reinforcing the vapor chamber 36 and a function of fixing the vapor chamber 36 to the motherboard 24 through the studs 52.

FIG. 5 is a schematic sectional view of the chassis 14. FIG. 6 is a sectional perspective view of the vapor chamber 36 and the CPU 30, and a part of a peripheral area thereof.

As illustrated in FIG. 5 and FIG. 6, a reinforcing frame 54 is fixed (by, for example, adhesive tape) to the rear surface 24b of the motherboard 24. The reinforcing frame 54 is formed by, for example, punching a metal plate. The reinforcing frame 54 is rectangular, and the inner rectangular shape thereof is substantially equal to the outer rectangular shape of the CPU 30. The reinforcing frame 54 is placed in such a manner as to surround the CPU 30 in a transparent plan view. Further, the upper surface 36d of the vapor chamber 36 is in contact with the CPU 30 through the heat receiving plate 30b. The heat receiving plate 30b is a plate formed of a metal having high thermal conductivity, such as copper or aluminum.

Four mounting holes 56 are formed in the motherboard 24. At the four corners of the reinforcing frame 54, through holes 54a are formed at positions where the through holes 54a are in communication with the mounting holes 56. The four through holes 54a and the four mounting holes 56 are provided at positions corresponding to the screw holes 52a of the studs 52. The studs 52 and the motherboard 24 are fixed by the four screws 58. In other words, the threaded portions of the screws 58 are screwed into the studs 52 through the through holes 54a and the mounting holes 56 so as to cause heads 58a to press the rear surface 24b through the reinforcing frame 54, thereby fixing the motherboard 24 and the vapor chamber 36. A small gap is secured between the front surface 24a and the end surfaces of the studs 52. Therefore, the contact pressure between the CPU 30 and the vapor chamber 36 can be sufficiently increased by adjusting the tightening of the screws 58.

Springs 60 are provided between the reinforcing frame 54 and the heads 58a of the screws 58. The springs 60 act to facilitate the removal of the screws 58 from the studs 52 when removing the screws 58, and also act as spring washers. The screws 58 may be provided with a function to prevent slippage from the reinforcing frame 54.

Thus, in the electronic apparatus 10 according to the present embodiment, the screws 58 come out to the front surface 24a from the rear surface 24b of the motherboard 24 through the mounting holes 56, and then are screwed to the studs 52 thereby to fix the vapor chamber 36. The studs 52 are provided on the upper surface 36d, which is one surface of the vapor chamber 36. The screws 58 are screwed in from above, and have lengths set such that the distal ends thereof do not come in contact with the upper surface 36d.

Therefore, the screws 58 do not come in contact with or pass through the vapor chamber 36, thus eliminating the need for providing through holes or recessed portions for the screws 58. This makes it possible to secure a constant thickness over substantially the whole surface of the vapor chamber 36, and there is no performance loss, and effective use of the cooling effect can be achieved. The vapor chamber 36 has a flat plate shape because there is no through hole through which the screws 58 pass, and even if a target heat generating element were located at a position different from that of the CPU 30, it would be sufficient to replace only the frame 46 with an appropriate one. The vapor chamber 36 has a simple shape with no through hole, thus making it possible to reduce the manufacturing cost.

In terms of design, there is freedom in the position where the studs 52 are to be provided, and the studs 52 can be placed in the vicinity of the four corners of the CPU 30. In the present embodiment, the studs 52, the screws 58, and the mounting holes 56 are provided four each, and are provided at positions in the vicinity of the four corners of the CPU 30, so that the vapor chamber 36 and the CPU 30 can be brought into contact with each other under a moderately strong pressure, thus making it possible to improve the heat transfer performance. Further, since the reinforcing frame 54 is provided on the rear surface 24b of the motherboard 24, the motherboard 24 will not be deformed even if the screws 58 are firmly screwed.

As described above, the keyboard 20 is provided on the cover member 14A, which is the upper surface of the chassis 14, and the cover member 14A has a substantially bathtub shape with the open bottom. The keyboard 20 is removably attached to the bathtub-shaped portion of the cover member 14A. As illustrated in FIG. 5, the motherboard 24 is provided such that the rear surface 24b is on the upper side, and the heads 58a of the screws 58 are exposed at the top of the chassis 14 with the keyboard 20 removed. In other words, the heads 58a of the screws 58 are accessible from openings 62 of the bathtub-shaped portion in the cover member 14A.

In the assembly process of the electronic apparatus 10, the lower cover member 14B is removed in advance, the motherboard 24, on which the CPU 30 has been mounted, is fixed to the cover member 14A, and then the vapor chamber 36 is positioned at a predetermined position, and the screws 58 are operated through the openings 62 to screw the screws 58 into the studs 52. Thereafter, the cover member 14B and the keyboard 20 are installed to the cover member 14A thereby to complete the assembly of the chassis 14.

The cooling module 22 including the vapor chamber 36 may include some structurally vulnerable portions, but can be prevented from being damaged in the assembly process by attaching the cooling module 22 later to the motherboard 24, which has been stabilized by being fixed to the cover member 14A. Further, the openings 62 are provided so as to enable the screws 58 to be operated when the rear surface 24b of the motherboard 24 is on the upper side. The openings 62 are covered by the keyboard 20 and are not visible to a user. Depending on the conditions in the assembly process, the motherboard 24 may be attached to the cover member 14B after fixing the vapor chamber 36 to the motherboard 24 by the screws 58.

In the electronic apparatus 10 according to the present embodiment, the vapor chamber 37 (refer to FIG. 3) adopts a fixing structure different from that of the vapor chamber 36 on the basis of design conditions such as a layout. Depending on the design conditions, the fixing structure for the vapor chamber 37 and the sub-board 25 may have the same fixing structure between the vapor chamber 36 and the motherboard 24. The objects to be cooled by the vapor chambers 36 and 37 are not limited to the CPU 30 and the GPU 31, and may be other heat generating elements.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF SYMBOLS

10 electronic apparatus
12, 14 chassis
14A, 14B cover member
20 keyboard
24 motherboard (substrate)
24a mounting surface (front surface)
24b rear surface
30 CPU (heat generating element)
36 vapor chamber
36d upper surface
36e lower surface
46, 47 frame
46b, 46c frame bar
46a frame portion
46ba, 46ca parallel portion
46bb, 46cb proximate portion
52 stud
54 reinforcing frame
54a through hole
56 mounting hole
58 screw
58a head
60 spring
62 opening

What is claimed is:

1. An electronic apparatus comprising:
a chassis;
a substrate which is provided in the chassis and has a heat generating element mounted on a front surface thereof;
a plate-shaped vapor chamber having a working fluid sealed in a hermetically sealed space formed between two metal plates;
a stud fixed to one surface of the vapor chamber; and
a screw fixing the stud and the substrate, wherein
the heat generating element is thermally connected to the one surface of the vapor chamber,
a mounting hole is formed in the substrate, and
the screw is screwed to the stud through the mounting hole from a rear surface of the substrate.

2. The electronic apparatus according to claim 1, wherein
the heat generating element is rectangular, and
the stud, the screw, and the mounting hole are provided four each at positions in the vicinity of four corners of the heat generating element.

3. The electronic apparatus according to claim 2, wherein
two frame bars are provided on the one surface of the vapor chamber,
each of the frame bars includes:
a parallel portion that extends along two parallel edges of the heat generating element; and
a proximate portion which extends further from the parallel portion in both directions and expands in a direction in which the distance between the two narrows, and
the studs are provided on the proximate portion.

4. The electronic apparatus according to claim 2, wherein
a reinforcing frame shaped along an outline of the heat generating element is provided on a rear surface of the substrate, and
through holes which are in communication with the mounting holes and through which the screws pass are formed in the reinforcing frame.

5. The electronic apparatus according to claim 1, wherein
a detachable keyboard is provided on an upper surface of the chassis,
the substrate is provided such that a rear surface thereof is on an upper side, and
a head of the screw is exposed at the top of the chassis in a state in which the keyboard has been removed.
